(19) United States
(12) Patent Application Publication
(10) Pub. No.: US 2007/0178637 A1
(43) Pub. Date: Aug. 2, 2007

(54) Method of fabricating gate of semiconductor device using oxygen-free ashing process

(75) Inventors: Hyung-suk Jung, Gyeonggi-do (KR); Cheol-kyu Lee, Gyeonggi-do (KR); Jong-ho Lee, Gyeonggi-do (KR); Sung-kee Han, Gyeonggi-do (KR); Yun-seok Kim, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/699,784

(22) Filed: Jan. 30, 2007

(30) Foreign Application Priority Data
Jan. 31, 2006 (KR) 10-2006-0009366

(51) Int. Cl. H01L 21/8238

(52) U.S. Cl. 438/216; 257/E21.436

(57) ABSTRACT

A method of fabricating a gate of a semiconductor device using an oxygen-free ashing process is disclosed. The method includes forming a high-k dielectric film, having a dielectric constant higher than a silicon oxide film, on a semiconductor substrate including an NMOS region and a PMOS region, forming an etching target film on the high-k dielectric film, forming a photoresist pattern to expose any one region of the two regions, on the etching target film, etching the etching target film using the photoresist pattern as an etching mask, and removing the photoresist pattern using plasma formed in the presence of an oxygen-free reactive gas.

### CROSS-REFERENCE TO RELATED APPLICATION

This application claims priority from Korean Patent Application No. 10-2006-0009366 filed on Jan. 31, 2006 in the Korean Intellectual Property Office, the disclosure of which is incorporated herein by reference in its entirety.

### FIELD OF THE INVENTION

The present invention relates to methods of fabricating semiconductor devices, and more particularly, to methods of fabricating semiconductor device gates.

### BACKGROUND OF THE INVENTION

In the fabrication of semiconductors, a photolithographic process includes applying a photoresist on a semiconductor substrate to form a photoresist layer, selectively exposing the photoresist layer to light, developing the exposed photoresist layer to form a photoresist pattern, etching the region of the semiconductor substrate which is not screened by the photoresist, and removing the photoresist pattern used as the etching mask through an ashing process. As such, the ashing process is a type of etching process functioning to remove the useless photoresist after the etching process or ion implantation process. The ashing process is conducted using plasma in the presence of oxygen (O₂) as a reactive gas. Thus, the ashing process for removing the photoresist may result in a reaction between the photoresist and oxygen, and thus is considered an oxidation procedure.

Recently, with the increase in the degree of integration and speed of semiconductor devices in semiconductor fabrication technologies, a transistor may be required to have further improved properties. As such, since the properties of the transistor are greatly affected by the material of a gate dielectric film, a detailed gate formation process may be required. However, the gate dielectric film may be deteriorated when passing through a plurality of process steps. Especially, in the case where oxygen gas is used to create plasma in the ashing process, a gate dielectric film reacts with oxygen, undesirably increasing the thickness of the dielectric film and forming a charge trap site in the dielectric film. In this way, when the gate dielectric film becomes thick and the charge trap site is created, problems such as high threshold voltage of the transistor and deterioration of leakage properties and reliability may be caused. Moreover, such problems may occur when an ashing process is conducted in a state of the gate dielectric film being exposed.

Further, in order to increase the operability of the transistor, the gate dielectric film may be formed using a high-k dielectric film, having a dielectric constant higher than a conventional silicon oxide film. At this time, however, the above problems may become more serious. The high-k dielectric film is used as the gate dielectric film, leading to threshold voltages of NMOS and PMOS different from each other depending on the type of high-k dielectric film. In the case where the gate dielectric film is formed using a hafnium nitride-oxide film under channel ion implantation conditions the same as an ion implantation process applied when using a silicon oxide film as the gate dielectric film, the NMOS has a threshold voltage of about +0.5 V, and the PMOS has a threshold voltage of about −1.1 V. In addition, hafnium nitride-alumina, such as HfAlON, requires both NMOS and PMOS to have a threshold voltage of 0.8 V, which is difficult to decrease. In addition, the use of an aluminum oxide film (Al₂O₃) results in a threshold voltage of the PMOS the same as that of the silicon oxide film and a threshold voltage of the NMOS greater by about 1 V than that of the silicon oxide film. As such, with the intention of solving such problems, when the gate dielectric film is formed of high-k material, NMOS and PMOS are formed of high-k materials different from each other. That is, the NMOS is formed of hafnium oxide, and the PMOS is formed of aluminum oxide, such that the threshold voltage of each of the NMOS and PMOS is similar to that of silicon oxide film. Further, when metal material is used as a gate electrode, since the metal material has an invariable work function under conditions of ion implantation, a dual metal gate having respective materials suitable for NMOS and PMOS is required. Therefore, when high-k dielectric films different from each other are provided as the gate dielectric film or when gate electrodes different from each other are respectively applied to the NMOS and PMOS, the ashing process should be conducted in a state in which the gate dielectric film is exposed. Especially, in the case where hafnium oxide based material is applied to the high-k dielectric film, the conventional oxygen ashing process suffers because it drastically deteriorates the gate dielectric film, due to the very fast diffusivity of oxygen (O₂).

### SUMMARY OF THE INVENTION

According to a first embodiment of the present invention, a method of fabricating a semiconductor device includes forming a high-k dielectric film, having a dielectric constant higher than a silicon oxide film, on a semiconductor substrate including an NMOS region and a PMOS region; forming an etching target film on the high-k dielectric film; forming a photoresist pattern to expose any one region of the two regions, on the etching target film; etching the etching target film using the photoresist pattern as an etching mask; and removing the photoresist pattern using plasma formed in the presence of an oxygen-free reactive gas.

According to a second embodiment of the present invention, a method of fabricating a semiconductor device includes forming a first high-k dielectric film, having a dielectric constant higher than a silicon oxide film, on a semiconductor substrate including an NMOS region and a PMOS region; forming a second high-k dielectric film, having a dielectric constant different from that of the first high-k dielectric film, on the first high-k dielectric film; forming a photoresist pattern to expose the NMOS region, on the second high-k dielectric film; etching the second high-k dielectric film using the photoresist pattern as an etching mask; and removing the photoresist pattern using plasma formed in the presence of an oxygen-free reactive gas.

According to a third embodiment of the present invention, a method of fabricating a semiconductor device includes forming a high-k dielectric film, having a dielectric constant higher than a silicon oxide film, on a semiconductor substrate including an NMOS region and a PMOS region; forming a single-layer conductive film or a multilayer conductive film on the high-k dielectric film; forming a photoresist pattern on the conductive film; etching all of the single-layer conductive film or all of the multilayer conductive film with the exception of a first layer thereof, using the photoresist pattern as an etching mask; and removing the photoresist pattern using plasma formed in the presence of an oxygen-free reactive gas.

### BRIEF DESCRIPTION OF THE DRAWINGS

The above and other objects, features and advantages of the present invention will be more clearly understood from the following detailed description taken in conjunction with the accompanying drawings, in which:

FIGS. 1A to 1G illustrate a process of fabricating a gate of a semiconductor device, according to a first embodiment of the present invention;

FIGS. 2A to 2E illustrate a process of fabricating a gate of a semiconductor device, according to a second embodiment of the present invention;

FIGS. 3A to 3D illustrate a process of fabricating a gate of a semiconductor device, according to a third embodiment of the present invention; and

FIG. 4 is a graph showing the thickness of a gate dielectric film of the present invention and a gate dielectric film fabricated using a conventional oxygen ashing process.

### DESCRIPTION OF EMBODIMENTS OF THE INVENTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. Moreover, each embodiment described and illustrated herein includes its complementary conductivity type embodiment as well. Like numbers refer to like elements throughout.

It will be understood that when an element or layer is referred to as being “on”, “connected to” and/or “coupled to” another element or layer, it can be directly on, connected or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” may include any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms may be used to distinguish one element, component, region, layer and/or section from another region, layer and/or section. For example, a first element, component, region, layer and/or section discussed below could be termed a second element, component, region, layer and/or section without departing from the teachings of the present invention.

Spatially relative terms, such as “below”, “lower”, “above”, “upper” and the like, may be used herein for ease of description to describe an element and/or a feature's relationship to another element(s) and/or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the example term “below” can encompass both an orientation of above and below. The device may be otherwise oriented (rotated 90° or at other orientations) and the spatially relative descriptors used herein interpreted accordingly. Moreover, the term “beneath” indicates a relationship of one layer or region to another layer or region relative to the substrate, as illustrated in the figures.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof. Example embodiments of the invention are described herein with reference to plan and cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

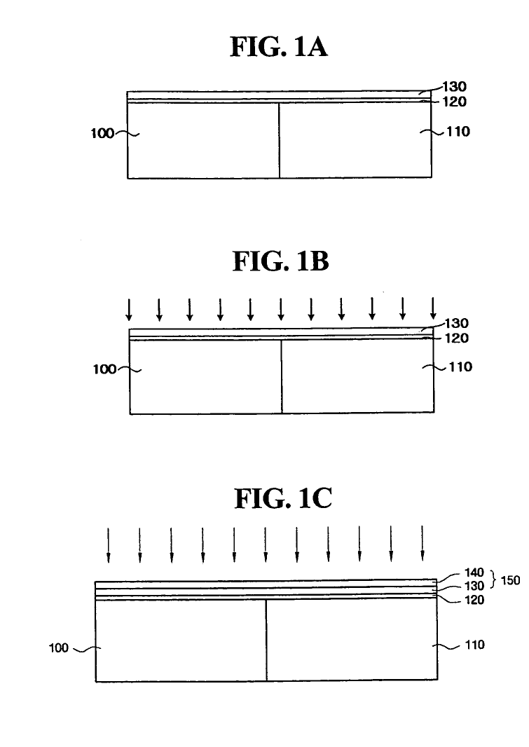

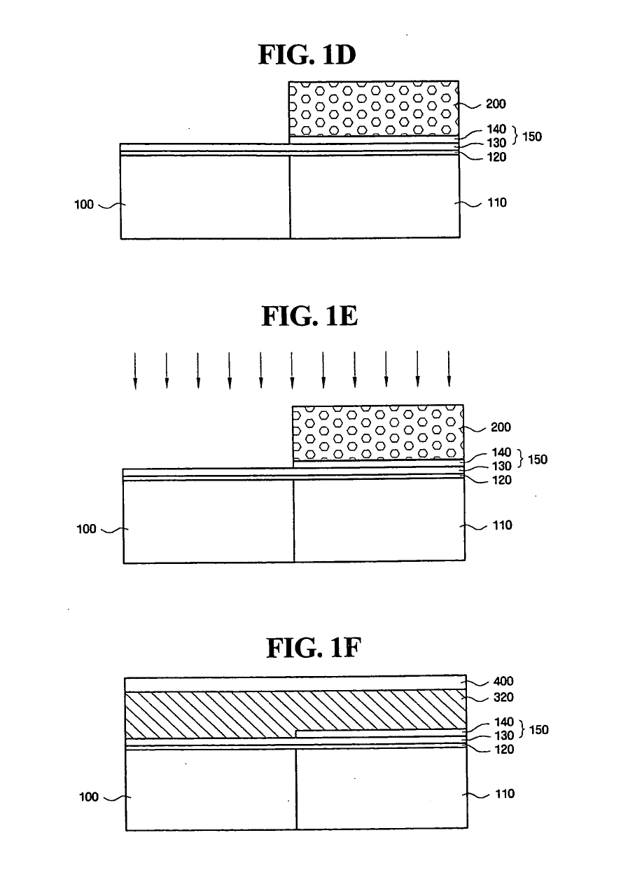

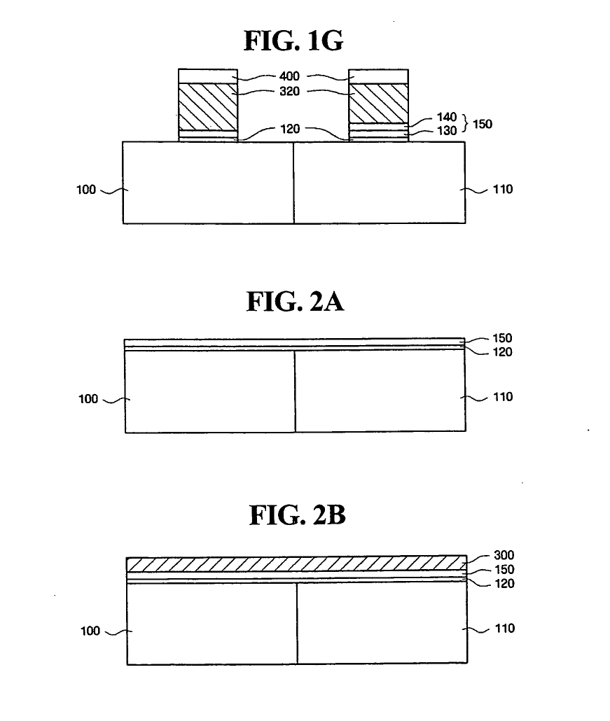

FIGS. 1A to 1G are sectional views of a semiconductor device showing the process of fabricating a semiconductor device using an oxygen-free ashing process, according to a first embodiment of the present invention.

As shown in FIG. 1A, an NMOS region 100 and a PMOS region 110 are formed on a substrate, and an interfacial layer 120 is formed before forming a lower gate dielectric film 130. The interfacial layer 120, serving to prevent a reaction between the lower gate dielectric film 130 and the silicon substrate, may be formed to a thickness of 1.5 nm or less through a cleaning process using, for example, ozone (O₃) gas or ozone-containing ozone water, or alternatively may be omitted. After the formation of the interfacial layer 120, the lower gate dielectric film 130 is formed. In addition, a silicon oxide film (not shown) may be provided between the interfacial layer 120 and the lower gate dielectric film 130. In the case where a gate dielectric film has a stacked structure, the lower gate dielectric film 130 may be part of the gate dielectric film. On the other hand, in the case where a gate dielectric film has a single-layer structure, the lower gate dielectric film 130 may constitute the entire gate dielectric film. In the case where a high-k dielectric film is applied, the lower gate dielectric film 130 may be formed with a hafnium oxide based dielectric film that is obtained by using hafnium chloride (HfCl₄) and H₂O as reactants or using an alkyl-amide type hafnium precursor, H₂O and O₃ through atomic layer deposition (ALD). In addition, a hafnium oxide film may be formed using a hafnium precursor such as Hf-t-butoxide or Hf-NMP in the presence of O₂, O₃ or radical oxygen through CVD. In addition, a hafnium oxide film may result from deposition of hafnium and then thermal oxidation. In addition to the hafnium oxide film thus formed, a metal, such as zirconium (Zr), tantalum (Ta), titanium (Ti), aluminum (Al), platinum (Pt), ruthenium (Ru), rubidium (Rb), or molybdenum (Mo), is coupled with oxygen, thus forming a high-k oxide film having dielectric film properties.

As shown in FIG. 1B, after the formation of the lower gate dielectric film 130, PDA-1 (Post Densification Annealing) is performed to make the lower gate dielectric film 130 dense so as to decrease the etching rate of a chemical solution for cleaning and curing defects of the dielectric film. Alternatively, such a process may be omitted depending on the type of material used for the lower gate dielectric film 130. Preferably, PDA-1 may be carried out at about 750˜1050° C. using N₂, NO, N₂O, O₂, NH₃, or gas mixtures thereof.

As shown in FIG. 1C, an upper gate dielectric film 140 is formed on the lower gate dielectric film 130. As such, although both the lower gate dielectric film 130 and the upper gate dielectric film 140 constitute a gate dielectric film 150 in the drawing, either the lower gate dielectric film 130 or the upper gate dielectric film 140 may be provided to constitute a gate dielectric film 150. The upper gate dielectric film 140 may be formed of material different from that of the lower gate dielectric film 130. For example, when the lower gate dielectric film 130 is formed of hafnium oxide, the upper gate dielectric film 140 may be formed of aluminum oxide. The aluminum oxide film may be deposited using TMA (Tri-Metal Aluminum), H₂O, and O₃ as reactants through ALD or may be formed through deposition of aluminum and thermal oxidation. With the goal of preventing the aluminum oxide film from being etched in a subsequent cleaning process, PDA-2 may be conducted. It is preferred that PDA-2 be performed at 450˜1050° C. in an atmosphere containing Ar, N₂, NO, N₂O, O₂, NH₃, or gas mixtures thereof, or in a vacuum.

As shown in FIG. 1D, a photoresist 200 is applied on the upper gate dielectric film 140, and then subjected to exposure and development, thus forming a mask pattern. Using such a photoresist 200 as the mask pattern, the upper gate dielectric film 140 of the NMOS region 100, which is provided beneath the photoresist 200, is selectively etched. When the upper gate dielectric film is formed of aluminum oxide, an etching source containing fluorine (F) is used. Also, when a wet etching process is used, an etchant containing fluorine (F) is useful. Thereby, the NMOS region 100 includes only the lower gate dielectric film 130 thereon, while the PMOS region 110 includes a stacked structure of the lower gate dielectric film 130 and the upper gate dielectric film 140 thereon. Specifically, the hafnium oxide film is provided on the NMOS region 100, and the stacked structure of the hafnium oxide film and the aluminum oxide film is provided on the PMOS region 110. Alternatively, upon the formation of the pattern of the photoresist 200, the NMOS region 100 is screened by the photoresist 200 and the PMOS region is exposed, after which the upper gate dielectric film 140 is etched. Thereby, the NMOS region 100 may include a gate dielectric film having a stacked structure, while the PMOS region 110 may include a single-layer gate dielectric film composed entirely of the lower gate dielectric film 130.

As shown in FIG. 1E, the photoresist 200 is removed through an ashing process after etching the upper gate dielectric film 140. As such, the ashing process is conducted by creating plasma using at least one oxygen-free reactive gas selected from among hydrogen, nitrogen, ammonia, helium, and argon and then removing the photoresist 200 using the plasma. In addition, a fluorine-containing gas such as CF₄ is further added to the above reactive gas, thus increasing the efficiency of removal of the photoresist 200. In the present invention, since the ashing process does not require the use of oxygen, the gate dielectric films 130, 140 are formed without an increase in thickness and without deterioration. Moreover, in the case where the gate dielectric film 150 is formed using hafnium oxide having high oxygen diffusivity, it may be minimally deteriorated.

As shown in FIG. 1F, a gate electrode 320 and a gate mask 400 are formed. The gate electrode 320 includes at least one conductor selected from among a conductive silicon film, a metal film, a conductive metal oxide film, a conductive metal nitride film, and a metal silicide film. The conductive silicon film is a silicon film added with boron (B), phosphorus (P), arsenic (As), indium (In), or mixtures thereof. The metal film is formed of W, Mo, Ti, Ta, Al, Hf, Zr, Pt, Ru, Rd, Ni, Co, or mixtures thereof. The conductive metal oxide film is formed of a combination of the metal film and oxygen, and the conductive metal nitride film is formed of a combination of the metal film and nitrogen. In addition, the metal silicide film may be formed of a combination of the metal film and silicon. The gate mask 400, which is a patterning mask for patterning the gate, may be formed of an insulator, or alternatively a conductor.

As shown in FIG. 1G, the gate mask 400 is patterned, after which an etching process is conducted, thus forming a gate pattern on each of the NMOS region 100 and the PMOS region 110. The etching process is exemplified by dry etching and wet etching.

Subsequently, according to process steps known to those skilled in the field of semiconductor devices, steps of forming a spacer in each of the transistors, forming an interlayer insulating layer, forming wires in the transistors for input and output of electrical signals, forming a passivation layer on the substrate, and packing the substrate are additionally conducted, thereby completing the semiconductor device.

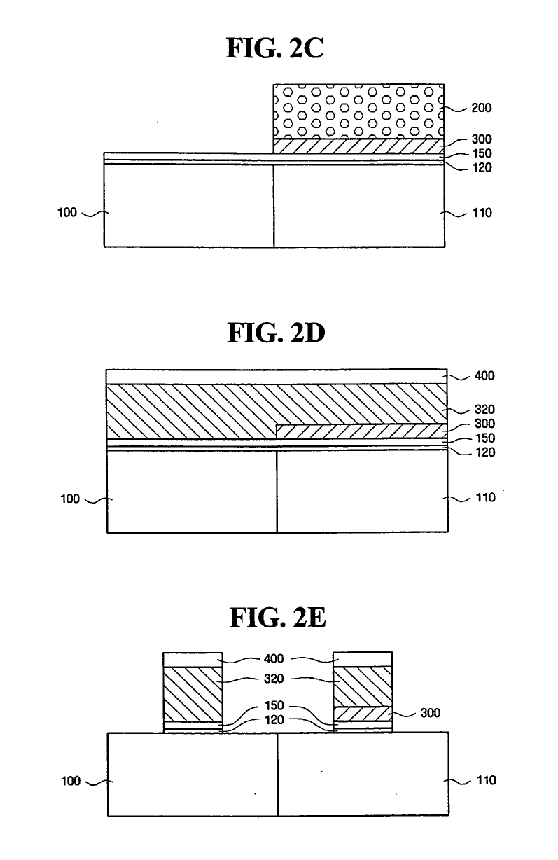

FIGS. 2A to 2E are sectional views showing the process of fabricating a semiconductor device using an oxygen-free ashing process, according to a second embodiment of the present invention.

As shown in FIG. 2A, an NMOS region 100 and a PMOS region 110 are formed, and an interfacial layer 120 and a gate dielectric film 150 are formed, as described above. In addition, a silicon oxide film (not shown) may be provided between the interfacial layer 120 and the gate dielectric film 150, and, alternatively, the interfacial layer 120 may be omitted. The gate dielectric film 150 may be provided in the form of a single-layer structure or a stacked structure, and also may be formed with a high-k dielectric film. When using the high-k dielectric film, the examples of the high-k dielectric film described above may be applied. Thereafter, although not shown in the drawing, PDA-1 may be conducted.

As shown in FIG. 2B, a conductive film 300 is formed to a thickness of 200 Å or less on the gate dielectric film 150. In the case where the conductive film 300 of the PMOS region 110 is removed, other than the conductive film 300 of the NMOS region 100, a conductive metal having a work function of about 4.0˜4.4 eV is used. On the other hand, in the case where the conductive film 300 of the NMOS region 100 is removed, other than the conductive film 300 of the PMOS region 110, a conductive metal having about 4.8˜5.1 eV is used. As such, the conductive metal includes at least one conductor selected from among a metal film, a conductive metal oxide film, a conductive metal nitride film, and a metal silicide film, each of which is formed using W, Mo, Ti, Ta, Al, Hf, Zr, Pt, Ru, Rd, Ni, Co, or mixtures thereof.

As shown in FIG. 2C, a photoresist 200 is applied on the conductive film 300 and then subjected to exposure and development, thus forming a mask pattern. Using such a photoresist 200 as the mask pattern, the conductive film 300 of the NMOS region 100 is selectively etched. After the etching process, the NMOS region 100 includes only the gate dielectric film 150 thereon, while the PMOS region 110 includes a stacked structure of the gate dielectric film 150 and the conductive film 300 thereon. Specifically, in the case where the gate dielectric film 150 is formed with a high-k dielectric film using hafnium oxide, the hafnium oxide film is provided on the NMOS region 100, and the stacked structure of the hafnium oxide film and the conductive film 300 is provided on the PMOS region 110. Alternatively, upon the formation of the pattern of the photoresist 200, the NMOS region 100 is screened by the photoresist 200 and the PMOS region is exposed, after which the gate dielectric film 150 is etched. If so, the NMOS region 100 includes a stacked structure of the gate dielectric film 150 and the conductive film 300 thereon, while the PMOS region 110 includes only the gate dielectric film 150 thereon.

As shown in FIG. 2D, after etching the conductive film 300 that is formed beneath the photoresist 200, the photoresist 200 is removed through an ashing process, and then a gate electrode 320 and a gate mask 400 are formed. As such, the ashing process is conducted by forming plasma using at least one oxygen-free reactive gas selected from among hydrogen, nitrogen, ammonia, helium, and argon and then removing the photoresist 200 using the plasma. In addition, a fluorine-containing gas such as CF₄ is further added to the reactive gas, thus increasing the efficiency of removal of the photoresist 200. Since the ashing process does not require the use of oxygen, the gate dielectric film 150 may be formed without an increase in thickness and without deterioration. In particular, in the case where the gate dielectric film 150 is formed using a hafnium oxide based film having high oxygen diffusivity, it may be minimally deteriorated. The gate electrode 320 includes at least one conductor selected from among a conductive silicon film, a metal film, a conductive metal oxide film, a conductive metal nitride film, and a metal silicide film. The conductive silicon film is a silicon film added with boron (B), phosphorus (P), arsenic (As), indium (In), or mixtures thereof. The metal film is formed of W, Mo, Ti, Ta, Al, Hf, Zr, Pt, Ru, Rd, Ni, Co, or mixtures thereof. The conductive metal oxide film is formed of a combination of the metal film and oxygen, and the conductive metal nitride film is formed of a combination of the metal film and nitrogen. In addition, the metal silicide film may be formed of a combination of the metal film and silicon. Moreover, in order to realize a dual gate, in the case where the conductive film 300 is formed using a conductive metal having a work function of about 4.0˜4.4 eV, the gate electrode 320 may be formed of a conductor of about 4.8˜5.1 eV. Alternatively, in the case where the conductive film 300 is formed using a conductive metal having a work function of about 4.8˜5.1 eV, the gate electrode 320 may be formed of a conductor of about 4.0˜4.4 eV. The gate mask 400 functions as a patterning mask for patterning the gate, and may be composed of an insulating film, or alternatively a conductive film.

As shown in FIG. 2E, the gate mask 400 is patterned, and an etching process is performed, thus forming a gate pattern on each of the NMOS region 100 and the PMOS region 110. As such, the etching process is exemplified by dry etching and wet etching.

Subsequent processes, which are substantially the same as those described with reference to FIGS. 1A to 1G, may proceed, and thus a detailed description thereof is omitted.

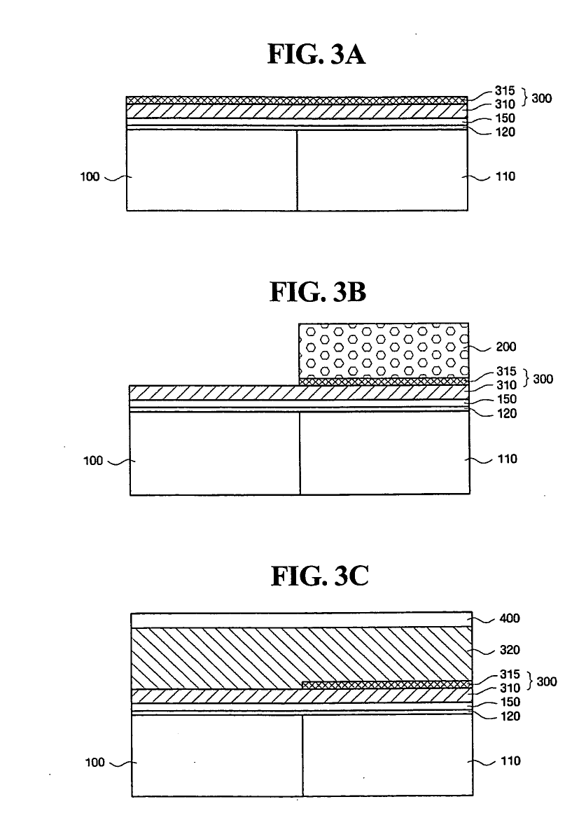

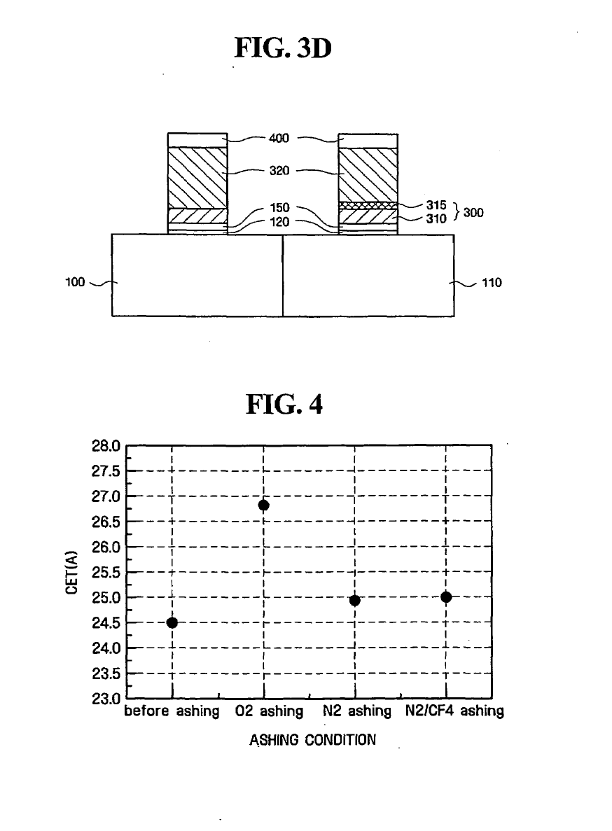

FIGS. 3A to 3D are sectional views of a semiconductor device showing the process of fabricating a semiconductor device using an oxygen-free ashing process, according to a third embodiment of the present invention.

As shown in FIG. 3A, an NMOS region 100 and a PMOS region 110 are formed, and an interfacial layer 120 and a gate dielectric film 150 are formed, through processes the same as those of the fabrication method according to the embodiments mentioned above. On the gate dielectric film 150, a multilayer conductive film 300 having a stacked structure of a first conductive film 310 and a second conductive film 315 is formed. The first conductive film 310 is 200 Å thick or less, and the second conductive film 315 is formed of material different from that of the first conductive film 310 and functions to modulate the work function of the first conductive film 310. The first conductive film 310 and the second conductive film 315 may be formed of any conductor selected from among a metal film, a conductive metal oxide film, a conductive metal nitride film, and a metal silicide film, each of which is formed using W, Mo, Ti, Ta, Al, Hf, Zr, Pt, Ru, Rd, Ni, Co, or mixtures thereof.

As shown in FIG. 3B, a photoresist 200 is applied on the upper conductive film 315, and then subjected to exposure and development, thus forming a mask pattern. Using such a photoresist 200 as the mask pattern, the second conductive film 315 of the NMOS region 100 is selectively etched. After the etching process, the NMOS region 100 includes only the first conductive film 310 thereon, while the PMOS region 110 includes a stacked structure of the first conductive film 310 and the second conductive film 315 thereon. Specifically, in the case where the gate dielectric film 150 is formed using a hafnium oxide film which is a high-k dielectric film, the hafnium oxide film and the first conductive film 310 are provided on the NMOS region 100, and a stacked structure of the hafnium oxide film, the first conductive film 310, and the second conductive film 315 is provided on the PMOS region 110. Alternatively, upon the formation of the pattern of the photoresist 200, the NMOS region 100 is screened by the photoresist 200 and the PMOS region is exposed, after which the second conductive film 315 is etched, such that the NMOS region 100 may include a stacked structure of the hafnium oxide film, the first conductive film 310, and the second conductive film 315 thereon, and the PMOS region 110 may include a stacked structure of the hafnium oxide film and the first conductive film 310 thereon.

As shown in FIG. 3C, the photoresist 200 is removed through an ashing process, and a gate electrode 320 and a gate mask 400 are formed. As such, the ashing process is conducted by forming plasma using at least one oxygen-free reactive gas selected from among hydrogen, nitrogen, ammonia, helium, and argon, and then removing the photoresist 200 using the plasma. In addition, a fluorine-containing gas such as CF₄ is further added to the reactive gas, thus increasing the efficiency of removal of the photoresist 200. Since the ashing process does not require the use of oxygen, the gate dielectric film 150 may be formed without an increase in thickness and without deterioration. Especially, in the case where the gate dielectric film 150 is formed using hafnium oxide having high oxygen diffusivity, it may be minimally deteriorated. The gate electrode 320 includes at least one conductor selected from among a conductive silicon film, a metal film, a conductive metal oxide film, a conductive metal nitride film, and a metal silicide film. The conductive silicon film is a silicon film added with boron (B), phosphorus (P), arsenic (As), indium (In), or mixtures thereof. The metal film is formed of W, Mo, Ti, Ta, Al, Hf, Zr, Pt, Ru, Rd, Ni, Co, or mixtures thereof. The conductive metal oxide film is formed of a combination of the metal film and oxygen, and the conductive metal nitride film is formed of a combination of the metal film and nitrogen. In addition, the metal silicide film may be formed of a combination of the metal film and silicon. The gate mask 400 serves as a patterning mask for patterning the gate, and may be composed of an insulating film, or alternatively a conductive film.

As shown in FIG. 3D, the gate mask 400 is patterned, and an etching process is performed, thus forming a gate pattern on each of the NMOS region 100 and the PMOS region 1110. As such, the etching process is exemplified by dry etching and wet etching.

Subsequent processes, which are substantially the same as those described with reference to FIGS. 1A to 1G, are carried out, and thus a detailed description thereof is omitted.

FIG. 4 is a graph showing the thickness of each of the gate dielectric film of the NMOS according to the present invention and a conventional dielectric film. As the gate dielectric film, a hafnium oxide film was provided on the NMOS, while a stacked structure of a hafnium oxide film and an aluminum oxide film was provided on the PMOS. After the formation of the gate dielectric film, when conducting an ashing process using oxygen, the thickness of the hafnium oxide film was further increased by about 2.5 Å compared to before the ashing process. However, in the case of conducting an oxygen-free ashing process using nitrogen or a combination of nitrogen and CF₄, the thickness of the gate dielectric film was increased by 0.5 Å or less. From this, the oxygen-free ashing process of the present invention was confirmed to considerably mitigate the problem of the increase in the thickness of the dielectric film, compared to a conventional oxygen ashing process.

As described hereinbefore, the present invention provides a method of fabricating a gate of a semiconductor device using an oxygen-free ashing process. According to the present invention, when the gate dielectric film of a transistor is formed, a photoresist is removed through an oxygen-free ashing process, thus preventing problems of an increase in the thickness of the gate dielectric film and deterioration of reliability and leakage properties.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A method of fabricating a semiconductor device, the method comprising:
forming a high-k dielectric film, having a dielectric constant higher than a silicon oxide film, on a semiconductor substrate including an NMOS region and a PMOS region;
forming an etching target film on the high-k dielectric film;
forming a photoresist pattern to expose any one region of the two regions, on the etching target film;
etching the etching target film using the photoresist pattern as an etching mask; and
removing the photoresist pattern using plasma formed in the presence of an oxygen-free reactive gas.

2. The method of claim 1, wherein the high-k dielectric film is a dielectric film comprising hafnium, and the etching target film is a high-k dielectric film comprising aluminum.

3. The method of claim 1, wherein the photoresist pattern is used to expose the NMOS region, and the etching target film has a work function of 4.0˜4.4 eV.

4. The method of claim 1, wherein the photoresist pattern is used to expose the PMOS region, and the etching target film is a single-layer conductive film having a work function of 4.8˜5.1 eV.

5. The method of claim 1, wherein the photoresist pattern is used to expose the NMOS region, and the etching target film is a double-layer conductive film comprising a lower layer having a work function of 4.0˜4.4 eV and an upper layer having a work function of 4.8˜5.1 eV, the upper layer being etched when etching the etching target film.

6. The method of claim 1, wherein the photoresist pattern is used to expose the PMOS region, and the etching target film comprises a lower layer having a work function of 4.8˜5.1 eV and an upper layer having a work function of 4.0˜4.4 eV, the upper layer being etched when etching the etching target film.

7. The method of claim 1, wherein the reactive gas comprises at least one gas selected from the group consisting of hydrogen, nitrogen, ammonia, helium, and argon, or further comprises the at least one gas and a fluorine-containing gas.

8. A method of fabricating a semiconductor device, the method comprising:
forming a first high-k dielectric film, having a dielectric constant higher than a silicon oxide film, on a semiconductor substrate including an NMOS region and a PMOS region;
forming a second high-k dielectric film, having a dielectric constant different from that of the first high-k dielectric film, on the first high-k dielectric film;
forming a photoresist pattern to expose the NMOS region, on the second high-k dielectric film;
etching the second high-k dielectric film using the photoresist pattern as an etching mask; and
removing the photoresist pattern using plasma formed in the presence of an oxygen-free reactive gas.

9. The method of claim 8, wherein the first high-k dielectric film is a dielectric film comprising hafnium, and the second high-k dielectric film is a dielectric film comprising aluminum.

10. The method of claim 9, wherein the dielectric film comprising hafnium is HfO₂, HfₓSi₁₋ₓO_{y}, or HfₓSi₁₋ₓON.

11. The method of claim 9, further comprising making the first high-k dielectric film dense after forming the first high-k dielectric film, and making the second high-k dielectric film dense after forming the second high-k dielectric film.

12. The method of claim 9, further comprising treating a surface of the semiconductor substrate with ozone gas or ozone-containing ozone water to form an interfacial layer, before forming the first high-k dielectric film.

13. The method of claim 8, wherein the reactive gas comprises at least one gas selected from the group consisting of hydrogen, nitrogen, ammonia, helium, and argon, or further comprises the at least one gas and a fluorine-containing gas.

14. A method of fabricating a semiconductor device, the method comprising:
forming a high-k dielectric film, having a dielectric constant higher than a silicon oxide film, on a semiconductor substrate including an NMOS region and a PMOS region;
forming a single-layer conductive film or a multilayer conductive film on the high-k dielectric film;
forming a photoresist pattern on the conductive film;
etching all of the single-layer conductive film or all of the multilayer conductive film with the exception of a first layer thereof, using the photoresist pattern as an etching mask; and
removing the photoresist pattern using plasma formed in the presence of an oxygen-free reactive gas.

15. The method of claim 14, wherein the high-k dielectric film is a dielectric film comprising hafnium.

16. The method of claim 15, wherein the dielectric film comprising hafnium is HfO₂, HfₓSi₁₋ₓO_{y}, or HfₓSi₁₋ₓON.

17. The method of claim 14, wherein the photoresist pattern is used to expose the NMOS region, and the single-layer conductive film is a conductive film having a work function of 4.0˜4.4 eV.

18. The method of claim 14, wherein the photoresist pattern is used to expose the PMOS region, and the single-layer conductive film is a conductive film having a work function of 4.8˜5.1 eV.

19. The method of claim 14, wherein the photoresist pattern is used to expose the NMOS region, and the multilayer conductive film comprises the first layer having a work function of 4.0˜4.4 eV and a second layer having a work function of 4.8˜5.1 eV, the second layer being etched when etching the conductive film.

20. The method of claim 19, wherein the second layer comprises two conductive layers different from each other such that the multilayer conductive film is a triple-layer conductive film.

21. The method of claim 14, wherein the photoresist pattern is used to expose the PMOS region, and the multilayer conductive film comprises the first layer having a work function of 4.8˜5.1 eV and a second layer having a work function of 4.0˜4.4 eV, the second layer being etched when etching the conductive film.

22. The method of claim 21, wherein the second layer comprises two conductive layers different from each other such that the multilayer conductive film is a triple-layer conductive film.

23. The method of claim 14, wherein the reactive gas comprises at least one gas selected from the group consisting of hydrogen, nitrogen, ammonia, helium, and argon, or further comprises the at least one gas and a fluorine-containing gas.

24. The method of claim 14, further comprising forming a conductive film for a gate electrode on the semiconductor substrate, after removing the photoresist.
